(19) United States
(12) Patent Application Publication
(10) Pub. No.: US 2025/0158451 A1
(43) Pub. Date: May 15, 2025

(54) Efficiency Control in Wireless Charging Systems

(71) Applicant: Apple Inc., Cupertino, CA (US)

(72) Inventors: Damiano Patron, South San Francisco, CA (US); Wei Li, Cupertino, CA (US); Xiaomeng Wang, Round Rock, TX (US)

(21) Appl. No.: 18/652,662

(22) Filed: May 1, 2024

Related U.S. Application Data
(60) Provisional application No. 63/597,432, filed on Nov. 9, 2023.

(51) Int. Cl. H02J 50/10; H02J 7/00; H04R 1/02; H04R 3/04; H05K 7/20

(52) U.S. Cl. CPC H02J 50/10; H02J 7/0047; H02J 7/007192; H04R 1/028; H04R 3/04; H05K 7/20136; H05K 7/20209

(57) ABSTRACT

A wireless charging system may include a wireless power receiving device that receives wireless power signals form a wireless power transmitting device. To reduce temperature of the wireless power receiving device during wireless charging operations, an air-circulating component may at least intermittently circulate air within an interior cavity that includes wireless charging components.

This application claims the benefit of U.S. provisional patent application No. 63/597,432, filed Nov. 9, 2023, which is hereby incorporated by reference herein in its entirety.

### FIELD

This relates generally to power systems and, more particularly, to wireless power systems for charging electronic devices.

### BACKGROUND

In a wireless charging system, a wireless power transmitting device transmits wireless power to a wireless power receiving device. The wireless power receiving device charges a battery and/or powers components using the wireless power. Under some usage conditions, temperature of a wireless power transmitting device and/or a wireless power receiving device may increase during wireless charging operations.

### SUMMARY

An electronic device may include one or more components forming an interior cavity, one or more wireless charging components disposed in the interior cavity, a speaker at least partially exposed to the interior cavity and an external environment; and control circuitry disposed in the interior cavity and configured to, in accordance with detecting a temperature condition, use the speaker to circulate air in the interior cavity.

### BRIEF DESCRIPTION OF THE DRAWINGS

FIG. 1 is a schematic diagram of an illustrative wireless power system in accordance with some embodiments.

FIG. 2 is a cross-sectional top view of an illustrative power receiving device with a speaker, one or more internal cavities, and one or more wireless charging components in accordance with some embodiments.

FIG. 3 is a cross-sectional side view of an illustrative power receiving device with a speaker, one or more internal cavities, and thermal interface material in accordance with some embodiments.

FIG. 4 is a graph of the state of charge of a battery in an illustrative power receiving device in different scenarios in accordance with some embodiments.

FIG. 5 is a timeline showing how an illustrative air-circulating component may be activated intermittently in accordance with some embodiments.

FIG. 6 is a flowchart of an illustrative method that may be performed by a power receiving device in accordance with some embodiments.

FIG. 7 is a mode diagram showing illustrative operating modes for a speaker in a power receiving device in accordance with some embodiments.

### DETAILED DESCRIPTION

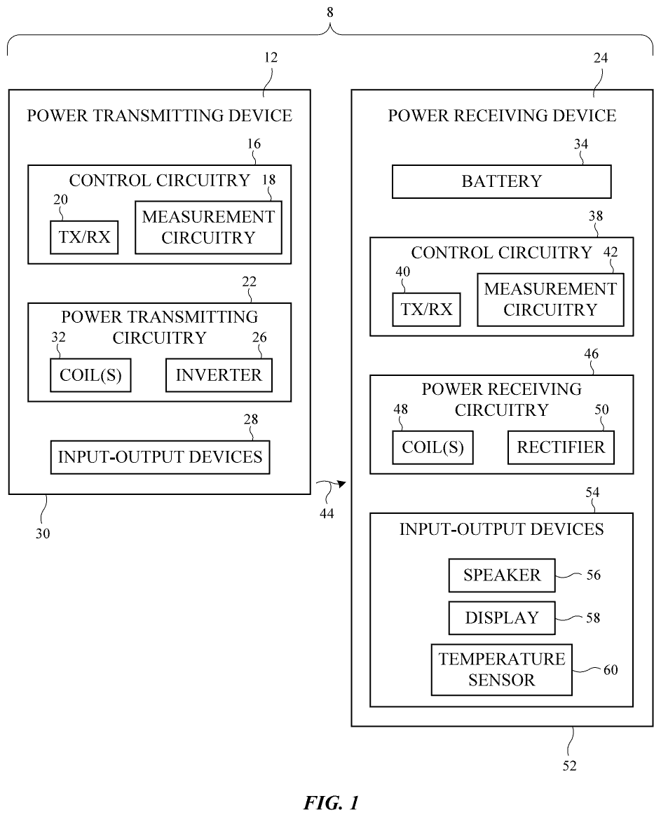

An illustrative wireless power system (also sometimes called a wireless charging system) is shown in FIG. 1. As shown in FIG. 1, wireless power system 8 may include one or more wireless power transmitting devices such as wireless power transmitting device 12 and one or more wireless power receiving devices such as wireless power receiving device 24. Wireless power system 8 may sometimes also be referred to herein as wireless power transfer (WPT) system 8 or wireless power system 8. Wireless power transmitting device 12 may sometimes also be referred to herein as power transmitter (PTX) device 12 or simply as PTX 12. Wireless power receiving device 24 may sometimes also be referred to herein as power receiver (PRX) device 24 or simply as PRX 24.

PTX device 12 includes control circuitry 16. Control circuitry 16 is mounted within housing 30. PRX device 24 includes control circuitry 38 mounted within a corresponding housing 52 for PRX device 24. Exemplary control circuitry 16 and control circuitry 38 are used in controlling the operation of WPT system 8. This control circuitry may include processing circuitry that includes one or more processors such as microprocessors, power management units, baseband processors, digital signal processors, microcontrollers, graphics processing units (GPUs), central processing units (CPUs), application processors (APs), application-specific integrated circuits with processing circuits, and/or other processing circuits. The processing circuitry implements desired control and communications features in PTX device 12 and PRX device 24. For example, the processing circuitry may be used in controlling power to one or more coils, determining and/or setting power transmission levels, generating and/or processing sensor data (e.g., to detect foreign objects and/or external electromagnetic signals or fields), processing user input, handling negotiations between PTX device 12 and PRX device 24, sending and receiving in-band and out-of-band data, making measurements, and/or otherwise controlling the operation of WPT system 8.

Control circuitry in WPT system 8 (e.g., control circuitry 16 and/or 38) is configured to perform operations in WPT system 8 using hardware (e.g., dedicated hardware or circuitry), firmware and/or software. Software code for performing operations in WPT system 8 is stored on non-transitory computer readable storage media (e.g., tangible computer readable storage media) in the control circuitry of WPT system 8. The software code may sometimes be referred to as software, data, program instructions, instructions, or code. The non-transitory computer readable storage media may include non-volatile memory such as non-volatile random-access memory (NVRAM), one or more hard drives (e.g., magnetic drives or solid state drives), one or more removable flash drives or other removable media, or the like. Software stored on the non-transitory computer readable storage media may be executed on the processing circuitry of control circuitry 16 and/or 38.

PTX device 12 may be a stand-alone power adapter (e.g., a wireless charging mat or charging puck that includes power adapter circuitry), may be a wireless charging mat or puck that is connected to a power adapter or other equipment by a cable, may be an electronic device (e.g., a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses, goggles, or other equipment worn on a user's head, or other wearable or miniature device, a television, a computer display that does not contain an embedded computer, a gaming device, a navigation device, a wireless internet-connected voice-controlled speaker, a home entertainment device, a remote control device, a gaming controller, a peripheral user input device, a wireless base station or access point, equipment that implements the functionality of two or more of these devices, or other electronic equipment), may be equipment that has been incorporated into furniture, a vehicle, or other system, may be a removable battery case, or may be other wireless power transfer equipment.

PRX device 24 may be an electronic device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses, goggles, or other equipment worn on a user's head, or other wearable or miniature device, a wireless tracking tag, a television, a computer display that does not contain an embedded computer, a gaming device, a navigation device, a wireless internet-connected voice-controlled speaker, a home entertainment device, a remote control device, a gaming controller, a peripheral user input device, a wireless base station or access point, equipment that implements the functionality of two or more of these devices, or other electronic equipment. Illustrative configurations in which PRX device 24 is a wristwatch device are described herein as an example.

PTX device 12 may be connected to a wall outlet (e.g., an alternating current power source), may be coupled to a wall outlet via an external power adapter, may have a battery for supplying power, and/or may have another source of power. In implementations where PTX device 12 is coupled to a wall outlet via an external power adapter, the adapter may have an alternating-current (AC) to direct-current (DC) power converter that converts AC power from a wall outlet or other power source into DC power. If desired, PTX device 12 may include a DC-DC power converter for converting the DC power between different DC voltages. Additionally or alternatively, PTX device 12 may include an AC-DC power converter that generates the DC power from the AC power provided by the wall outlet (e.g., in implementations where PTX device 12 is connected to the wall outlet without an external power adapter). DC power may be used to power control circuitry 16. During operation, a controller in control circuitry 16 uses power transmitting circuitry 22 to transmit wireless power to power receiving circuitry 46 of PRX device 24.

Power transmitting circuitry 22 may have switching circuitry, such as inverter circuitry 26 formed from transistors, that are turned on and off based on control signals provided by control circuitry 16 to create AC current signals through one or more wireless power transmitting coils such as wireless power transmitting coil(s) 32. These coil drive signals cause coil(s) 32 to transmit wireless power. In implementations where coil(s) 32 include multiple coils, the coils may be disposed on a ferromagnetic structure, arranged in a planar coil array, or may be arranged to form a cluster of coils (e.g., two or more coils, 5-10 coils, at least 10 coils, 10-30 coils, fewer than 35 coils, fewer than 25 coils, or other suitable number of coils). In some implementations, PTX device 12 includes only a single coil 32.

As the AC currents pass through one or more coils 32, alternating-current electromagnetic (e.g., magnetic) fields (wireless power signals 44) are produced that are received by one or more corresponding receiver coils such as coil(s) 48 in PRX device 24. In other words, one or more of coils 32 is inductively coupled to one or more of coils 48. PRX device 24 may have a single coil 48, at least two coils 48, at least three coils 48, at least four coils 48, or another suitable number of coils 48. When the alternating-current electromagnetic fields are received by coil(s) 48, corresponding alternating-current currents are induced in coil(s) 48. The AC signals that are used in transmitting wireless power may have any desired frequency (e.g., 100-400 kHz, 1-100 MHz, less than 2 MHz, between 100 kHz and 2 MHz, etc.). Rectifier circuitry such as rectifier circuitry 50, which contains rectifying components such as synchronous rectification transistors arranged in a bridge network, converts received AC signals (received alternating-current signals associated with wireless power signals 44) from one or more coils 48 into DC voltage signals for powering PRX device 24. Wireless power signals 44 are sometimes referred to herein as wireless power 44 or wireless charging signals 44. Coils 32 are sometimes referred to herein as wireless power transfer coils 32, wireless charging coils 32, or wireless power transmitting coils 32. Coils 48 are sometimes referred to herein as wireless power transfer coils 48, wireless charging coils 48, or wireless power receiving coils 48.

The DC voltage produced by rectifier circuitry 50 (sometime referred to as rectifier output voltage Vrect) can be used in charging a battery such as battery 34 and can be used in powering other components in PRX device 24 such as control circuitry 38, input-output (I/O) devices 54, etc. PTX device 12 may also include input-output devices such as input-output devices 28. Input-output devices 54 and/or input-output devices 28 may include input devices for gathering user input and/or making environmental measurements and may include output devices for providing a user with output.

As examples, input-output devices 28 and/or input-output devices 54 may include a display (screen) for creating visual output, a speaker for presenting output as audio signals, light-emitting diode status indicator lights and other light-emitting components for emitting light that provides a user with status information and/or other information, haptic devices for generating vibrations and other haptic output, and/or other output devices. Input-output devices 28 and/or input-output devices 54 may also include sensors for gathering input from a user and/or for making measurements of the surroundings of WPT system 8. In one possible arrangement, PRX device 24 is a wristwatch device with input-output devices 54 including a speaker 56, a display 58, and a temperature sensor 60.

The example in FIG. 1 of PRX device 24 including battery 34 is merely illustrative. If desired, an electronic device may include a supercapacitor to store charge instead of a battery. For example, PRX device 24 may include a supercapacitor in place of battery 34. Battery 34 may therefore sometimes be referred to as power storage device 34 or supercapacitor 34.

PTX device 12 and PRX device 24 may communicate wirelessly using in-band or out-of-band communications. Implementations using in-band communication may utilize, for example, frequency-shift keying (FSK) and/or amplitude-shift keying (ASK) techniques to communicate in-band data between PTX device 12 and PRX device 24. Wireless power and in-band data transmissions may be conveyed using coils 32 and 48 concurrently. When PTX 12 sends in-band data to PRX 24, wireless transceiver (TX/RX) circuitry 20 may modulate wireless charging signal 44 to impart FSK or ASK communications, and wireless transceiver circuitry 40 may demodulate the wireless charging signal 44 to obtain the data that is being communicated. When PRX 24 sends in-band data to PTX 12, wireless transceiver (TX/RX) circuitry 40 may modulate wireless charging signal 44 to impart FSK or ASK communications, and wireless transceiver circuitry 20 may demodulate the wireless charging signal 44 to obtain the data that is being communicated. Implementations using out-of-band communication may utilize, for example, hardware antenna structures and communication protocols such as Bluetooth or NFC to communicate out-of-band data between PTX device 12 and PRX device 24. Power may be conveyed wirelessly during out-of-band data transmissions. Wireless transceiver circuitry 20 may wirelessly transmit and/or receive out-of-band signals to and/or from PRX device 24 using an antenna. Wireless transceiver circuitry 40 may wirelessly transmit and/or receive out-of-band signals to and/or from PTX device 12 using an antenna.

Control circuitry 16 in PTX device 12 has measurement circuitry 18 that may be used to perform measurements of one or more characteristics external to PTX device 12. For example, measurement circuitry 18 may detect external objects on or adjacent the charging surface of the housing of PTX device 12. While shown in FIG. 1 as being separate from power transmitting circuitry 22 for the sake of clarity, measurement circuitry 18 may form a part of power transmitting circuitry 22 if desired.

Measurement circuitry 18 can detect foreign objects such as coils, paper clips, and other metallic objects, can detect the presence of PRX device 24 (e.g., circuitry 18 can detect the presence of one or more coils 48 and/or magnetic core material associated with coils 48), and/or can detect the presence of other power transmitting devices in the vicinity of PTX device 12 and/or WPT system 8. Measurement circuitry 18 can also be used to make sensor measurements using a capacitive sensor, can be used to make temperature measurements, and/or can otherwise be used in gathering information indicative of whether a foreign object, power transmitting device, power receiving device, or other external object (e.g., PRX device 24) is present on or adjacent to the coil(s) 32 of PTX device 12. If desired, PRX device 24 may include measurement circuitry 42. Measurement circuitry 42 may perform one or more of the measurements performed by measurement circuitry 18 (e.g., for or using coil(s) 48 on PRX device 24).

Each one of housing 30 and housing 52 may be formed from plastic, metal, fiber-composite materials such as carbon-fiber materials, wood and other natural materials, glass, other materials, and/or combinations of two or more of these materials. In one example, housing 52 for PRX 24 includes a display 58 (sometimes referred to as display screen 58) at a front face of the device, a glass layer at a rear face of the device, and a structure (sometimes referred to as a bezel structure, housing structure, etc.) between the display and the glass layer. The structure between the display and the glass layer may form a bezel for PRX 24 and may support one or more interior components of PRX 24 such as a main logic board (MLB). The structure may be formed from metal, as one example.

The example in FIG. 1 of PTX 12 transmitting wireless power and PRX 24 receiving wireless power is merely illustrative. PTX 12 may optionally be capable of receiving wireless power signals using coil(s) 32 and PRX 24 may optionally be capable of transmitting wireless power signals using coil(s) 48. When a device is capable of both transmitting and receiving wireless power signals, the device may include both an inverter and a rectifier.

During a wireless charging operation, wireless power signals 44 may be transmitted from PTX 12 to PTX 24 at a power transmission frequency. Rectifier circuitry 50 converts the received wireless power signals at one or more coils 48 into DC voltage signals for powering PRX device 24. During the wireless charging operation, heat may be generated by both PTX 12 and PRX 24. To ensure satisfactory wireless charging operations and satisfactory operation of both PTX 12 and PRX 24, it may be desirable to keep a temperature of PTX 12 and/or PRX 24 below a threshold temperature.

One technique to control temperature during wireless charging operations is to temporarily pause the wireless charging operation. Pausing the wireless charging operation may allow for heat to dissipate from PTX 12 and/or PRX 24. After the heat has dissipated and the temperature of PTX 12 and/or PRX 24 has returned to a target level, the wireless charging operation may be resumed. Temporarily pausing a wireless charging operation may be performed repeatedly whenever the temperature of PTX 12 and/or PRX 24 exceeds a target level. Temporarily pausing the wireless charging operation may therefore reduce the temperature in PTX 12 and/or PRX 24. However, temporarily pausing the wireless charging operation may increase a duration of time required to charge a battery 34 in PRX 24 to a target state of charge.

Another technique to control temperature during wireless charging operations is to use an air-circulating component to circulate air within PRX 24. PRX 24 may have an interior cavity defined by housing 52 that includes wireless charging components such as coil(s) 48 and rectifier 50. Coil(s) 48 and rectifier 50 may generate heat during a wireless charging operation. Circulating air within the interior cavity may cause convection-cooling of coil(s) 48, rectifier 50, and/or other components within PRX 24.

The air-circulating component may be a dedicated air-circulating component such as a fan. Alternatively, the air-circulating component may be speaker 56 for PRX 24. During a temperature control mode, speaker 56 may play a tone that causes air to be circulated within the interior cavity of PRX 24 and thereby cool PRX 24.

Using an air-circulating component to circulate air within PRX 24 may control temperature during wireless charging operations and may reduce the need for temporary pauses during the wireless charging operation. In other words, using an air-circulating component to circulate air within PRX 24 may decrease a duration of time required to charge battery 34 to a target state of charge while maintaining a temperature below a target level.

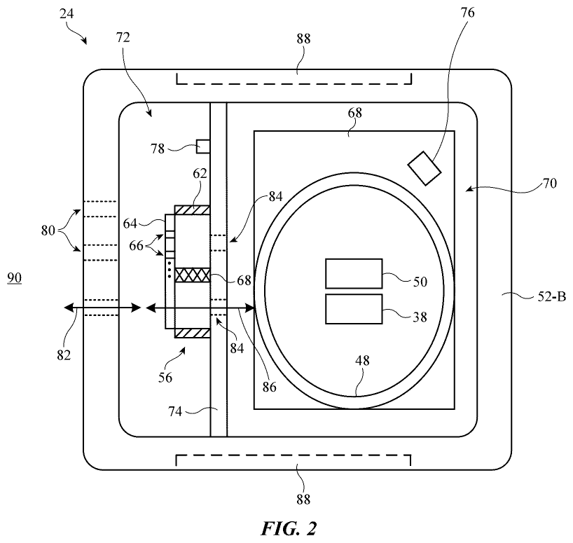

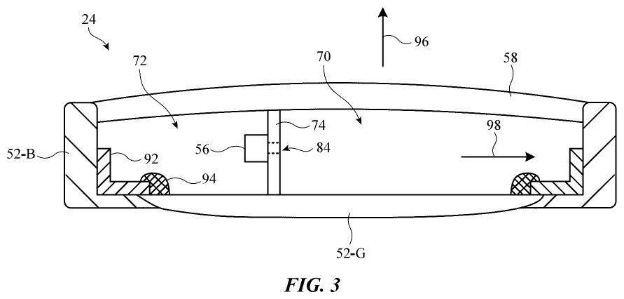

FIG. 2 is a cross-sectional top view of an illustrative PRX 24 including one or more air-circulating components. FIG. 2 shows a housing structure 52-B that extends around a periphery of the device. Housing structure 52-B may sometimes be referred to as bezel structure 52-B. Housing structure 52-B may be positioned between the display and a glass layer at a rear face of PRX 24 (see glass layer 52-G in the side view of FIG. 3). Housing structure 52-B may support one or more interior components of PRX 24 such as a main logic board 68. The structure may be formed from metal, as one example. Housing structure 52-B may have first and second channels 88 on opposing sides of PRX 24 that are each configured to receive at least a portion of a watch band.

Housing structure 52-B may at least partially define one or more interior cavities within PRX 24. FIG. 2 shows an example where housing structure 52-B at least partially defines a first interior cavity 70 and a second interior cavity 72. The example of labeling interior cavities 70 and 72 as separate interior cavities is merely illustrative and these volumes may instead be identified as first and second portions of a single interior cavity.

Interior cavities 70 and 72 may be separated by internal member 74. Internal member 74 may be integral with housing structure 52-B or may be a separate component (e.g., a circuit board, a brace, a flexible printed circuit, a membrane, etc.). In FIG. 2, internal member 74 is depicted as a straight component. This example is merely illustrative. In general, internal member 74 may have any desired shape or configuration. Additionally, the shape, size, and overall configuration of the first and second internal cavities 70 and 72 shown in FIG. 2 are illustrative examples, and other shapes, sizes, or overall configurations of the first and second interior cavities may also be used if desired.

One or more components may be positioned in the interior cavity 70. The components in interior cavity 70 may include processors, memory, batteries, haptic output devices, circuit boards, sensors, display components, wireless charging components, etc. FIG. 2 shows an example where rectifier 50, control circuitry 38, coil(s) 48, and fan 76 are formed on a printed circuit board 68 (sometimes referred to as main logic board 68) within interior cavity 70. This example is merely illustrative. One or more of these components may be formed at a separate location within interior cavity 70 if desired. In general, the components may be positioned within PRX 24 in any desired manner.

One or more components may be positioned in interior cavity 72. As shown in FIG. 2, interior cavity 72 includes speaker 56 and liquid-sensing element 78. The liquid-sensing element 78 (in conjunction with control circuitry 38) may detect the presence of liquid (e.g., water, sweat, etc.) within interior cavity 72 and may cause PRX 24 to take actions to eject the liquid or to otherwise operate differently due to the presence of the liquid. Components within interior cavity 72 may be electrically coupled (or otherwise communicatively coupled) to components within interior cavity 70 via wires, traces, flex circuits, or other conductors or conduits. Accordingly, the components in the first and second interior cavities 70 and 72 may communicate with one another. The electrical and/or communicative couplings may be substantially waterproof and/or impermeable to liquids or gasses.

Housing structure 52-B may include openings 80 in a side wall of the housing structure. The openings 80 may expose interior cavity 72 inside the housing structure to an external environment, thus allowing air pressure equalization between interior cavity 72 and the external environment (e.g., the ambient air around PRX 24). For example, the openings 80, which may be through-holes in the housing structure 52-B, may allow air flow into and out of interior cavity 72, as illustrated by arrow 82. In this way, the air pressure in interior cavity 72 may remain substantially the same as the ambient barometric air pressure.

Openings 80 may be configured to have a size and/or shape that allows air pressure equalization between the interior cavity 72 and the external environment in a substantially real-time basis. The openings 80 may be configured to allow air to flow at a flow rate (e.g., volumetric flow rate, mass flow rate) that allows changes in ambient barometric pressure to be reflected substantially immediately within interior cavity 72 (e.g., within 1 second or less). In some cases, the openings 80 may have a total opening area of about 2.0 mm², 2.5 mm², 3.0 mm², 3.5 mm², or 4.0 mm². In some cases the opening area may be smaller or larger (e.g., below 2.0 mm² or above 4.0 mm²).

Openings 80 may also benefit other components within interior cavity 72 such as speaker 56. Speaker 56 operates by moving air to produce sound. If the speaker 56 were placed in an air-sealed or fully enclosed volume, sound waves produced by the speaker 56 may be inaudible or otherwise muted. By placing speaker 56 in interior cavity 72 (which is exposed to the external environment by the openings 80), sound output from speaker 56 can exit the housing and be heard by a wearer of the device or other nearby person(s). In some cases, the total opening area of the openings 80, as well as the shape of the openings 80, may be configured to provide a desired acoustic performance.

When PRX 24 is exposed to water, sweat, or other liquids (e.g., due to the device being worn while swimming, showering, exercising in the rain, or the like), those liquids may enter interior cavity 72. Components such as speaker 56 and liquid-sensing element 78 may tolerate exposure to such liquids. However, other components within PRX 24 may not tolerate exposure to liquids well. Nevertheless, it may be desirable to include one or more openings 84 between interior cavities 70 and 72 to allow air to pass between the first and second interior cavities thereby equalizing air pressure between interior cavity 70 and the external environment. Without equalizing the pressure of interior cavity 70, damage may be caused by pressure differentials between interior cavity 70 and the external environment. Openings 84 may be referred to as pressure equalization valves or openings, and they may operate as or be a part of a barometric vent.

As shown in FIG. 2, openings 84 may extend through internal member 74, allowing air (and/or other gasses) to flow between the first and second interior cavities 70 and 72. The example of the openings being formed in internal member 74 is merely illustrative and the openings may be formed in other components and/or at other locations that allow air pressure equalization between the first and second interior cavities 70 and 72.

In the example of FIG. 2, speaker 56 is positioned over the openings 84. Accordingly, speaker 56 may also include openings 66 that allow passage of air, thus cooperating with openings 84 to define an air passage, illustrated by arrow 86, between the interior cavities 70 and 72. The positioning of speaker 56 over openings 84 further allows interior cavity 70 to act as a back volume for the speaker 56. For example, when the diaphragm 64 of the speaker 56 moves to generate sound output, changing air pressure behind the speaker 56 due to the movement of the diaphragm (e.g., between the speaker 56 and the internal member 74) may negatively affect the operation of the speaker 56. Openings 84 may alleviate or reduce the pressure variations by allowing air to flow into and out of interior cavity 70 during operation of the speaker 56. In this way, a separate speaker back-volume does not need to be defined to achieve satisfactory operation of the speaker 56.

It may be desirable to make interior cavity 70 resistant to water or liquid ingress. Accordingly, openings 84 may have a waterproofing membrane, seal, or other component that allows passage of air while limiting or preventing the passage of water. In some cases, the openings in the speaker 56 (e.g., openings in a speaker diaphragm) are sufficiently small to limit or prevent the passage of water. Accordingly, speaker 56 may act as an air-permeable waterproof membrane over the openings 84. In other cases, instead of or in addition to using the speaker diaphragm as an air-permeable waterproof membrane, another waterproof membrane may be positioned over the openings 84.

As used herein, an air-permeable waterproof membrane may correspond to any suitable material, component, device, assembly, or the like, that allows air (or other gasses) to pass therethrough, while preventing or limiting the passage of water (or other liquids) under a range of operating conditions for the device. For example, an air-permeable waterproof membrane may be waterproof up to a certain amount of fluid pressure or depth of immersion, beyond which the membrane may rupture or allow water to pass through. In the case of a wearable electronic device, such as a smart watch, the membrane may be waterproof up to an immersion depth of about 10 meters, about 20 meters, about 50 meters, about 100 meters, about 300 meters, or the like. The membrane may be any suitable component or material, such as a perforated metal, a perforated rigid polymer, a polymer film (e.g., expanded polytetrafluoroethylene, polyurethane, or the like), or the like.

Speaker 56 may optionally be used to eject liquid from interior cavity 72. Speaker 56 may produce a sound output (or otherwise move or introduce a pressure or force within interior cavity 72) that forces water out of the openings 80. The output from the speaker 56 may be any suitable output, such an inaudible pulsing, vibration, oscillation, or other motion of the diaphragm. In some cases, the output may be audible, and may be a tone of constant pitch and volume, or variable pitch and/or volume (e.g., a pulsing tone). The movement of the speaker 56, and more particularly the diaphragm of the speaker, may effectively push water out of the openings 80.

An active liquid-ejection technique as described above may be initiated manually (e.g., by a user initiating a water ejection function) or automatically. In the latter case, liquid-sensing element 78 positioned within interior cavity 72 detects the presence of liquid in the interior cavity 72 and automatically initiates the water ejection function. In some cases, the presence of liquid will cause the device to prompt a user (e.g., via the display 58) to initiate the water ejection function.

As shown in FIG. 2, speaker 56 includes a body 62, a diaphragm 64, and an actuation member 68. The actuation member 68 may be driven by a driver within the speaker. The actuation member 68 may be a voice coil motor or any other electrical or electromechanical system that moves diaphragm 64 to produce a sound output. Diaphragm 64 may optionally include openings 66 to allow air to pass through the diaphragm and openings 84 to equalize pressure between interior cavities 70 and 72. Openings in diaphragm 64 may have a size, shape, or other configuration that allows air to pass through while also preventing or restricting water or other liquids from passing through. Accordingly, the diaphragm 64 may operate as an air-permeable waterproof membrane. As a specific example, openings 66 may have a diameter of less than 1.0 mm, less than 0.5 mm, less than 0.25 mm, less than 0.1 mm, less than 0.05 mm, etc.

In some cases, speaker 56 may be a force-cancelling speaker assembly with multiple speaker subassemblies. Each speaker subassembly may include a respective diaphragm, body, and actuation member. The diaphragms of the two speaker subassemblies may be controlled to move in unison and with opposite phase such that the vibrations caused by either subassembly are cancelled out by the other subassembly. Using a force-cancelling speaker of this type may result in increased air-circulation during operation, which is advantageous when speaker 56 is used during temperature control operations.

As previously mentioned, speaker 56 may be used to eject liquid from interior cavity 72. Speaker 56 may also be used to circulate air within interior cavity 70 and/or 72 for temperature control purposes. During various conditions and operations (e.g., during wireless charging operations), the temperature within PRX 24 may exceed a threshold. When the temperature within PRX 24 is higher than a relevant threshold, speaker 56 moves diaphragm 64 to cause air circulation within PRX 24. Movement of diaphragm 64 may cause air to move between interior cavities 70 and 72 and/or between interior cavity 72 and external environment 90. Circulating air in this manner reduces the operating temperature of PRX 24 and, correspondingly, one or more components within the interior cavities (e.g., cooling of control circuitry 38, rectifier 50, coils 48, printed circuit board 68, etc.).

The example of using speaker 56 as an air-circulating component to control the temperature of RPX 24 is merely illustrative. Instead or in addition, a fan such as fan 76 may be used to circulate air to control the temperature of RPX 24. In embodiments where speaker 56 is used as an air-circulating component, fan 76 may optionally be omitted from PRX 24.

FIG. 3 is a cross-sectional side view of PRX 24 showing interior cavities 70 and 72. As shown in FIG. 3, PRX includes display 58 (sometimes referred to as display screen 58) at a front face of the device. Display 58 emits light in direction 96. Display 58 may include a transparent cover layer (e.g., formed from glass or sapphire) over a display panel. PRX 24 may also include a back cover 52-G. Back cover 52-G may be formed from or may include a dielectric material that is configured to allow electromagnetic fields such as wireless power signals 44 to pass therethrough. For example, back cover 52-G may be formed from glass. Back cover 52-G may be configured to allow or facilitate wireless charging of the device PRX 24 through the back cover. The back cover 52-G may also be completely or partially optically transparent or translucent, or otherwise allow optical sensing through all or a portion of the back cover.

Display 58, housing structure 52-B, and back cover 52-G may collectively be considered a housing for PRX 24. Display 58, housing structure 52-B, and back cover 52-G define interior cavities such as interior cavities 70 and 72.

FIG. 3 also shows an internal frame 92 and thermal interface material 94. Internal frame 92 may be coupled to housing structure 52-B and/or back cover 52-G. Internal frame 92 may support the back cover 52-G within PRX 24. Frame 92 may extend in a ring around the periphery of PRX 24. Thermal interface material 94 may also extend in a ring around the periphery of PRX 24. Thermal interface material 94 may directly contact frame 92. Thermal interface material 94 may have a relatively high thermal conductivity (e.g., greater than 0.1 W/(m*K), greater than 1 W/(m*K), greater than 1 W/(m*K), greater than 5 W/(m*K), greater than 10 W/(m*K), etc.).

As shown by arrow 98, air circulated within interior cavity 70 by speaker 56 may contact thermal interface material 94. Including thermal interface material 94 within PRX 24 may improve the temperature reduction caused by air circulation within the interior cavity. Thermal interface material 94 may be in direct contact with frame 92 and/or housing structure 52-B. Structures 92 and 52-B may be relatively large structures with relatively high thermal conductivities (e.g., greater than 0.1 W/(m*K), greater than 1 W/(m*K), greater than 1 W/(m*K), greater than 5 W/(m*K), greater than 10 W/(m*K), etc.). Including thermal interface material 94 in contact with structure 92 and/or 52-B may effectively provide a heat sink for heat to be dissipated during operation of PRX 24. Circulating air in contact with thermal interface material 94, frame 92, and/or housing structure 52-B causes heat to be spread amongst these components, lowering the internal temperature of PRX 24.

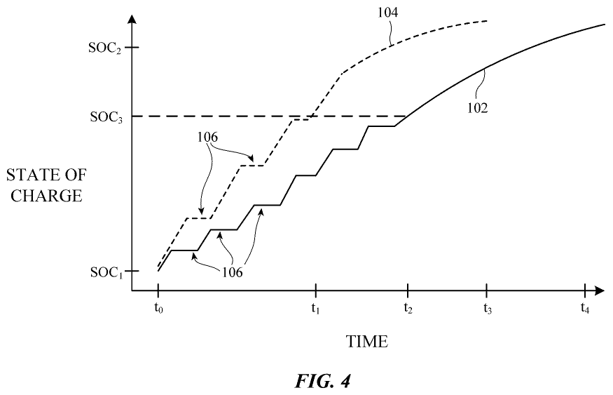

FIG. 4 is a graph of the state of charge of battery 34 of PRX 24 as a function of time in two different scenarios. In the first scenario, shown by profile 102, the only temperature control performed is temporarily pausing a wireless charging operation that is used to charge battery 34 of PRX 24. In the second scenario, shown by profile 104, in addition to temporarily pausing the wireless charging operation, air is at least intermittently circulated by an air-circulating component (such as speaker 56 or fan 76).

As shown by profile 102, the state of charge may rise when the wireless charging operation is active and may remain constant or gradually drop when the wireless charging operation is paused. In profile 102, there are 6 pauses 106 between t₀ and t₂ as the state of charge increases from state of charge SOC₁ to state of charge SOC₃. Each pause 106 may occur when, as an example, a temperature sensed by temperature sensor 60 exceeds a first temperature threshold. When the temperature exceeds the first threshold, the wireless charging operation may be paused for a given duration of time (e.g., one minute) and/or until the temperature drops below a threshold (e.g., the first temperature threshold or a second temperature threshold that is less than the first temperature threshold).

To reduce the total wireless charging time required, it may be desirable for the wireless charging operation to be paused as few times as possible. As shown by profile 104, using air-circulation for additional temperature control may reduce the number of pauses required during the wireless charging operation. In the example of FIG. 4, there are 3 pauses 106 between to and t₁ as the state of charge increases from state of charge SOC₁ to state of charge SOC₃. In other words, fewer pauses are present in profile 104 (with air-circulation for temperature control) than in profile 102 (without air-circulation for temperature control). As a consequence, the duration of time to charge battery 34 from SOC₁ to SOC₃ is shorter for profile 104 than for profile 102. Moreover, as shown in FIG. 4, the duration of time needed to sufficiently charge battery 34 (e.g., to SOC₂) is lower in profile 104 (where SOC₂ is reached at t₃) than in profile 102 (where SOC₂ is reached at t₄). Accordingly, charging efficiency of the wireless power transfer system is improved.

Different temperature conditions may trigger an air-circulation component in PRX 24 to circulate air within interior cavity 70. One condition is a temperature sensed by temperature sensor 60 exceeding a threshold. As an example, there may be a first temperature threshold above which an air-circulating component is used to circulate air and a second temperature threshold above which a wireless charging operation is paused. The second temperature threshold may be greater than the first temperature threshold (e.g., by at least one degree Celsius, by at least two degrees Celsius, by at least three degrees Celsius, etc.).

In some cases, temperature sensor 60 may be omitted from PRX 24. In these situations, a temperature condition that warrants air-circulation for temperature control may be inferred based on one or more non-temperature factors. Examples of non-temperature factors that may influence temperature of PRX 24 are a duration of time the PRX 24 has been performing a wireless charging operation, a frequency of the power transmission signals received during the wireless charging operation, and the state of charge of battery 34 during the wireless charging operation.

Wireless charging operations in PRX 24 may generate a current that generates heat. The heat generated during the wireless charging operation is proportional to the magnitude of the current (e.g., a higher current generates more heat and a lower current generates less heat). The current generated during the wireless charging operation may tend to be higher when the state of charge of battery 34 is relatively low (e.g., below SOC₃ in FIG. 4). SOC₃ may be 60%, as one example. A higher temperature may therefore be associated with wireless charging particularly when the SOC of battery 34 is relatively low and during the beginning of the wireless charging operation (when the SOC of battery 34 tends to be relatively low).

Therefore, control circuitry 38 may determine a temperature condition that warrants air-circulation for temperature control when a wireless charging operation is being performed and the duration of the wireless charging operation is less than a duration threshold. The magnitude of the duration threshold may be equal to, for example, less than 60 minutes, less than 45 minutes, less than 30 minutes, less than 15 minutes, etc.

Alternatively or additionally, control circuitry 38 may determine a temperature condition that warrants air-circulation for temperature control when a wireless charging operation is being performed and state of charge of battery 34 is less than a state of charge threshold. The magnitude of the state of charge threshold may be equal to, for example, less than 90%, less than 80%, less than 70%, less than 60%, less than 50%, less than 40%, less than 30%, less than 20%, less than 10%, etc.

Heat generation during wireless charging may also depend on the frequency of the power transmission signals 44. In one illustrative arrangement, PRX 24 may be operable at two power transmission frequencies (e.g., f₁ and f₂ where f₁<f₂). Wireless charging operations at the higher frequency f₂ may be associated with greater heat generation than wireless charging operations at the lower frequency f₁. Control circuitry 38 may therefore determine a temperature condition that triggers air-circulation based at least partially on the frequency of the power transmission signals 44.

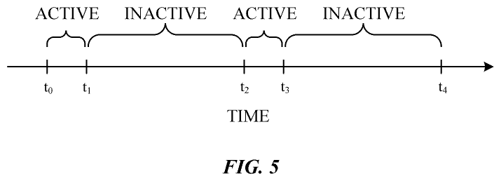

When control circuitry 38 detects a temperature condition and circulates air in the interior cavity, the air-circulating component may not necessarily be active at a 100% duty cycle. In other words, the air-circulating component may only intermittently be activated to circulate air, with inactive periods between the active periods. FIG. 5 is a timeline showing how the air-circulating component may be activated intermittently. As shown in FIG. 5, the air-circulating component is activated between t₀ and t₁ and circulates air during this time. The air-circulating component is then inactive between t₁ and t₂. The air-circulating component does not circulate air during the inactive periods. A cycle of an active period followed by an inactive period may be repeated, as shown by the active period between t₂ and t₃ and the inactive period between t₃ and t₄.

The ratio of time in each cycle in which the air-circulating component is active may be referred to as the duty cycle of the air-circulating component. The duty cycle may be less than 50%, less than 30%, less than 10%, less than 5%, less than 3%, less than 2%, less than 1%, etc. As one example, the air-circulating component may be cycled between active periods with a duration of 2 seconds and inactive periods with a duration of 2 minutes. In this case, the duty cycle is less than 2%. This duty cycle may be used for profile 104 in FIG. 4. As shown in FIG. 4, even at a low duty cycle of less than 2%, there are significant improvements in temperature control and wireless charging speed relative to an example where air circulation is not used.

When fan 76 is active for temperature control, the fan may rotate a blade to move air within interior cavity 70. When speaker 56 is active for temperature control, the speaker may play one or more tones at one or more frequencies. The speaker may play the one or more tones throughout each active period. Playing the tone(s) with speaker 56 may cause air to circulate within interior cavity 70 and/or interior cavity 72. It is noted that wireless charging operations may remain ongoing while the air-circulating component is intermittently activated as shown in FIG. 5.

The tones played by speaker 56 during temperature control operations may optionally be at a low frequency that is below (or close to) the lower audible limit of frequencies. As an example the frequency may be less than 100 Hz, less than 40 Hz, less than 30 Hz, less than 20 Hz, less than 10 Hz, between 10 Hz and 30 Hz, etc. Instead or in addition, the tones played by speaker 56 during temperature control operations may optionally be at a high frequency that is above (or close to) the upper audible limit of frequencies. As an example the frequency may be greater than 13 kHz, greater than 14 kHz, greater than 15 kHz, greater than 16 kHz, greater than 17 kHz, etc. These examples are merely illustrative. The tones played by speaker 56 during temperature control operations may, instead or in addition, include tones at audible frequencies between 20 Hz and 15 kHz, between 1 kHz and 10 kHz, between 8 kHz and 12 kHz, etc.

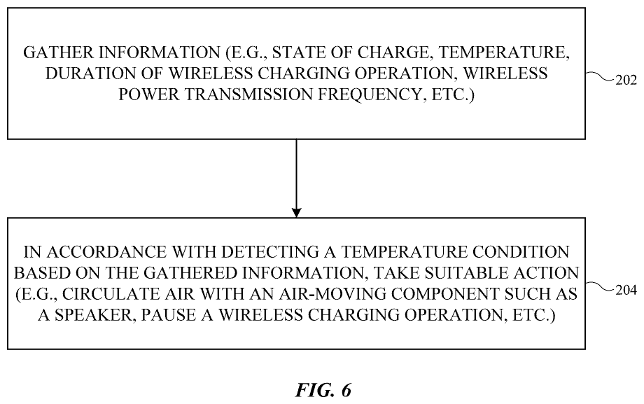

FIG. 6 is a flowchart of an illustrative method that may be performed by PRX 24 (e.g., control circuitry 38 in PRX 24). During the operations of block 202, control circuitry 38 may gather information. The gathered information may include information regarding the state of charge of battery 34, a temperature associated with PRX 24 (e.g., from one or more temperature sensors 60), a duration of a wireless charging operation, a wireless power transmission frequency of a wireless charging operation, and/or any other desired information. The information gathered during the operations of block 202 may be used by control circuitry 38 to assess a temperature of PRX 24.

During the operations of block 204, control circuitry 204 may, in accordance with detecting a temperature condition based on the gathered information from block 202, take suitable action. One illustrative action taken at block 204 may include using an air-circulating component such as fan 76 or speaker 56 to circulate air. Circulating the air may include circulating the air within an interior cavity that includes one or more wireless charging components. The circulated air may contact the wireless charging components and cool the wireless charging components (and, correspondingly, PRX 24). The circulated air may contact a thermal interface that is in a common interior cavity as the wireless charging components.

Circulating air using an air-circulating component may include intermittently activating the air-circulating component using a duty cycle as shown and discussed in connection with FIG. 5. When the air-circulating component is a speaker, the speaker may (when activated for temperature control) play one or more tones at one or more frequencies (e.g., frequencies less than 100 Hz, frequencies greater than 15 kHz, etc.).

Another illustrative action taken at block 204 may include temporarily pausing a wireless charging operation. Temporarily pausing the wireless charging operation may allow the temperature of PRX 24 to drop. After a given duration of time or after the temperature of PRX 24 has dropped to a target level, the wireless charging operation may be resumed. It is noted that during the temporary pause in the wireless charging operation, the PRX 24 may remain on a charging surface of PTX 12. In other words, the wireless charging operation may be paused for temperature control even though the positions of the PTX and PRX devices are unchanged.

The temperature condition detected at block 204 may include detecting that a temperature detected using one or more temperature sensors 60 is greater than a threshold temperature. A detected temperature greater than a first threshold may trigger activation of the air-circulating component. A detected temperature greater than a second threshold (that is greater than the first threshold) may trigger a temporary pause of the wireless charging operation.

The temperature condition detected at block 204 may include detecting that, while wireless charging operations are being performed, a state of charge of battery 34 is lower than a state of charge threshold. This condition may be indicative of a high temperature for PRX 24.

The temperature condition detected at block 204 may include detecting that, while a wireless charging operation is being performed, a duration of the wireless charging operation is less than a duration threshold. This condition may be indicative of a high temperature for PRX 24. It is noted that the duration of the wireless charging operation may be determined as the total time elapsing from the start of the wireless charging operation (including any temporary pauses).

The temperature condition detected at block 204 may include detecting the temperature condition during a wireless charging operation and based on the frequency of the wireless power signals received during the wireless charging operation. Wireless power signals at a high frequency may be indicative of a high temperature for PRX 24.

Any subset of the aforementioned factors may optionally be used in combination to detect the temperature condition at block 204.

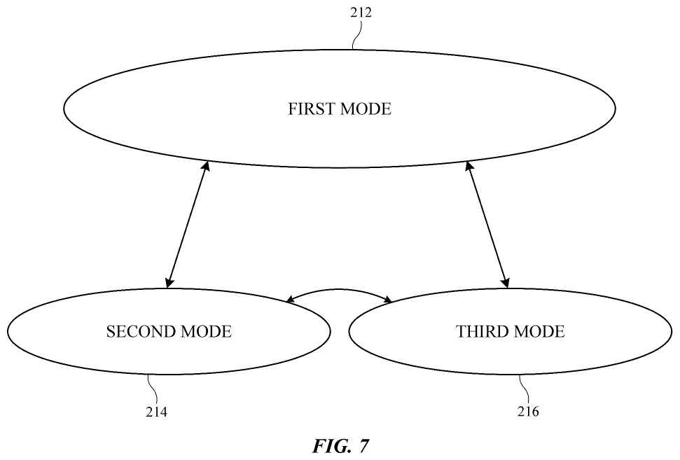

FIG. 7 is a mode diagram showing illustrative operating modes for speaker 56 in PRX 24. As shown, speaker 56 may be operable in a first mode 212 (sometimes referred to as audio mode 212), a second mode 214 (sometimes referred to as temperature control mode 214), and a third mode 216 (sometimes referred to as liquid expelling mode 216). In audio mode 212, speaker 56 may be used to play audio with the primary function of conveying sound to a user. In other words, speaker 56 may be operated in audio mode 212 when playing a ring tone (e.g., when an incoming telephone call is received), playing an alarm, playing music, etc. Speaker 56 may generate sound at frequencies that are audible to the human ear while in audio mode 212.

In temperature control mode 214, speaker 56 may play one or more tones that cause air to be circulated within interior cavity 70 and/or interior cavity 72 of PRX 24. In temperature control mode 214, speaker 56 plays audio with the primary function of circulating air for temperature reduction in PRX 24 (not conveying sound to a user). Accordingly, the tones played while in temperature control mode 214 may include tones at frequencies that are not audible (or barely audible) to the human ear.

In liquid expelling mode 216, speaker 56 may play one or more tones that cause water (or other liquids) to be expelled from interior cavity 72 of PRX 24. In liquid expelling mode 214, speaker 56 plays audio with the primary function of expelling liquids such as water from PRX 24 (not conveying sound to a user). Accordingly, the tones played while in liquid expelling mode 216 may include tones at frequencies that are not audible (or barely audible) to the human ear. Accordingly, speaker 56 may activate at different frequencies depending on whether it is operating under temperature mode 214, liquid expelling mode 216, and audio mode 212.

Although primarily described herein in relation to a power receiving device, it should be understood that the temperature control techniques described herein may also be used in a power transmitting device such as PTX 12. In other words, PTX 12 may use an air-circulating component such as a speaker to circulate air in response to detecting a temperature condition.

Similarly, although primarily described herein in relation to wireless charging operations, it should be understood that the temperature control techniques described herein may also be used during wired charging operations (e.g., when PRX 24 is plugged into a wired power source). In other words, PRX 24 may use an air-circulating component such as a speaker to circulate air in response to detecting a temperature condition during a wired charging operation. PRX 24 may also use air-circulation for temperature control even when the device is not being charged. For example, if PRX 24 is exposed to the sun, the air-circulation techniques described herein using speaker 56 may be used to lower the temperature of the device.

The foregoing is merely illustrative and various modifications can be made to the described embodiments. The foregoing embodiments may be implemented individually or in any combination.

What is claimed is:

1. An electronic device, comprising:
one or more components forming an interior cavity;
one or more wireless charging components disposed in the interior cavity;
a speaker at least partially exposed to the interior cavity and an external environment; and
control circuitry disposed in the interior cavity and configured to, in accordance with detecting a temperature condition, use the speaker to circulate air in the interior cavity.

2. The electronic device of claim 1, further comprising:
a temperature sensor configured to measure a temperature associated with the electronic device, wherein detecting the temperature condition comprises determining that the temperature associated with the electronic device is greater than a temperature threshold.

3. The electronic device of claim 2, wherein the control circuitry is configured to, while the temperature associated with the electronic device is greater than the temperature threshold, intermittently use the speaker to circulate air.

4. The electronic device of claim 2, wherein determining that the temperature associated with the electronic device is greater than the temperature threshold comprises determining that the temperature associated with the electronic device is greater than the temperature threshold during a wireless charging operation performed by the one or more wireless charging components and wherein using the speaker to circulate air comprises using the speaker to circulate air during the wireless charging operation.

5. The electronic device of claim 4, wherein the control circuitry is configured to at least temporarily pause the wireless charging operation in accordance with determining that the temperature associated with the electronic device is greater than an additional temperature threshold and wherein the additional temperature threshold is greater than the temperature threshold.

6. The electronic device of claim 1, further comprising:
a battery having a state of charge, wherein detecting the temperature condition comprises determining that the state of charge is below a state of charge threshold while a wireless charging operation is being performed by the one or more wireless charging components.

7. The electronic device of claim 6, wherein the control circuitry is configured to, while the state of charge is below the state of charge threshold and while the wireless charging operation is being performed by the one or more wireless charging components, intermittently use the speaker to circulate air.

8. The electronic device of claim 1, wherein detecting the temperature condition comprises determining that a duration of a wireless charging operation is less than a duration threshold.

9. The electronic device of claim 1, wherein detecting the temperature condition comprises:
detecting the temperature condition during a wireless charging operation performed by the one or more wireless charging components; and
detecting the temperature condition based at least partially on a frequency of wireless power signals received during the wireless charging operation.

10. The electronic device of claim 1, wherein using the speaker to circulate air comprises alternating between first periods in which the speaker is active and second periods in which the speaker is inactive and wherein a duration of the first periods is less than a duration of the second periods.

11. The electronic device of claim 10, wherein the duration of the first periods is less than 10% of the duration of the second periods.

12. The electronic device of claim 1, wherein the one or more charging components comprises a wireless charging coil and wherein the one or more charging components comprises rectifier circuitry.

13. The electronic device of claim 1, wherein using the speaker to circulate air comprises using the speaker to generate a tone with a frequency that is less than 100 Hz.

14. The electronic device of claim 13, wherein the frequency is between 10 Hz and 30 Hz.

15. The electronic device of claim 1, wherein using the speaker to circulate air comprises using the speaker to generate a tone with a frequency that is greater than 15 kHz.

16. The electronic device of claim 1, further comprising:
a thermal interface material in the interior cavity, wherein using the speaker to circulate air in the interior cavity causes the circulated air to contact the thermal interface material.

17. The electronic device of claim 1, wherein the speaker comprises a force-cancelling speaker with two speaker subassemblies.

18. The electronic device of claim 1, wherein the control circuitry is further configured to use the speaker to generate a tone with a frequency that is between 200 Hz and 10 kHz during operation of the electronic device outside of wireless charging operations.

19. A method of operating an electronic device that includes one or more components forming an interior cavity, one or more wireless charging components disposed in the interior cavity, and a speaker at least partially exposed to the interior cavity and an external environment, the method comprising:
in accordance with detecting a temperature condition, using the speaker to circulate air in the interior cavity.

20. A non-transitory computer-readable storage medium storing one or more programs configured to be executed by one or more processors of an electronic device that includes one or more components forming an interior cavity, one or more wireless charging components disposed in the interior cavity, and a speaker at least partially exposed to the interior cavity and an external environment, the one or more programs including instructions for:
in accordance with detecting a temperature condition, using the speaker to circulate air in the interior cavity.
